(19) United States
(12) Patent Application Publication
(10) Pub. No.: US 2006/0107892 A1
(43) Pub. Date: May 25, 2006

(54) Apparatus and method for fabricating preform for plastic optical fiber by successive UV polymerization

(75) Inventors: Young Mok Son, Hwaseong-Si (KR); Han Sol Cho, Yongin-Si (KR); Joon Yong Park, Yongin-Si (KR)

Correspondence Address: LEE & MORSE, P.C.;Attorneys and Counsellors At Law, SUITE 2000, 1101 WILSON BOULEVARD, ARLINGTON, VA, 22209, US

(73) Assignee: Samsung Electronics Co., Ltd.

(21) Appl. No.: 11/136,702

(22) Filed: May 25, 2005

(30) Foreign Application Priority Data
Nov. 25, 2004 (KR) 2004-97646

(51) Int. Cl. B29D 11/00; C30B 11/00

(52) U.S. Cl. 117/200; 117/900

(57) ABSTRACT

An apparatus and method of fabricating a preform for a plastic optical fiber including a rotary reactor, the rotary reactor including an introduction part having a reactant inlet through which a reactant is introduced into the rotary reactor and a reaction part that is separated from the introduction part by a blocking wall having a flow path through which the reaction part is connected with the introduction part, the flow path disposed at the center of the blocking wall, a UV blocking wall for preventing UV irradiation of the introduction part, a UV light-focusing optical system including a UV lamp and arranged over the rotary reactor, and a conveyor for transferring the UV light-focusing optical system in a radial direction of the rotary reactor.

### BACKGROUND OF THE INVENTION

1. Field of the Invention

The present invention relates to the formation of optical fiber preforms having a radially varying refractive index. More particularly, the present invention relates to a rotary reactor including an ultraviolet (UV) light-focusing optical system for inducing a polymerization reaction, and methods for fabricating a preform for plastic optical fiber using the same.

2. Description of the Related Art

Optical fibers used in the field of telecommunications are generally classified into a single-mode fiber and a multi-mode fiber in terms of the transmission mode of an optical signal. Optical fibers currently used for long distance, high speed communications are mostly step-index, single-mode optical fibers based on quartz glass. These optical fibers have a diameter as small as 5 microns to 10 microns, and as a result, these glass optical fibers face serious challenges in terms of achieving proper alignment and connection. Accordingly, these glass optical fibers are associated with high costs relating to achieving proper alignment and connection. Multi-mode glass optical fibers have a diameter that is larger than the diameter of single-mode optical fibers, and may be used for short distance communications such as in local area networks (LANs). However, these multi-mode glass optical fibers, in addition to being fragile, also suffer from high costs relating to achieving proper alignment and connection, and therefore are not widely used. Accordingly, these multi-mode glass optical fibers have been mainly used for short distance communication applications (up to 200 meters) such as in LANs, replacing traditional metal cabling such as twisted pair or coaxial cable. Since the data transmission capacity or bandwidth of metal cable is as low as about 150 Mbps, it cannot reach transmission speeds of 625 Mbps, which is a standard for the year 2000 for asynchronous transfer mode (ATM) communications, and thus it cannot satisfy future requirements for transmission capacity. To cope with these problems, the industry has expended great effort and investment over the past 10 years in the development of plastic optical fibers, which can be used in short distance communication applications such as LANs. The diameter of plastic optical fiber can be as large as 0.5 to 1.0 mm, which is 100 or more times than that of glass optical fiber, and, due to its flexibility, its alignment and connection are much easier issues than with plastic optical fibers. Moreover, since polymer-based connectors may be produced by compression molding, these connectors can be used both for alignment and for connection, and thereby reduce costs.

Plastic optical fiber may have a step-index (SI) structure, in which a refractive index changes stepwise in a radial direction, or a graded-index (GI) structure, in which a refractive index changes gradually in a radial direction. Since plastic optical fibers having an Si structure have high modal dispersion, the transmission capacity or bandwidth of a signal cannot be larger than that of metal cable. On the other hand, since plastic optical fibers having a GI structure have a low modal dispersion, they can have a large transmission capacity. Therefore, it is known that GI plastic optical fiber is adequate for use as a communication medium for short distance, high-speed communications because of reduced costs derived from its larger diameter and large capacity of data transmission derived from low modal dispersion.

Conventional methods for fabricating GI plastic optical fiber include photo-copolymerization using differences in reactivity and interfacial gel polymerization using a diffusion difference caused by molar volume. Similar techniques have been also been proposed. These methods fall mainly into two categories.

The first method is a batch process wherein a preliminary cylindrical molding product, a preform in which a refractive index changes in a radial direction, is fabricated. The resultant preform is then heated and drawn to fabricate GI plastic optical fiber. The second method is a continuous process, wherein a plastic fiber is produced by an extrusion process, and then low molecular weight material contained in the fiber is extracted, or contrarily introduced in a radial direction to obtain GI plastic optical fiber.

It is known that the first method directed to a batch process can successfully fabricate a GI plastic optical fiber having data transmission capacity of 2.5 Gbps, and that the second method could also successfully fabricate a plastic optical fiber having a relatively large data transmission capacity. However, these methods are limited by the refractive index and reactivity ratio, or the refractive index and molar volume of the chemical components, required for the process. In addition, when the methods are applied to fabricate a large-diameter preform, they have drawbacks in that uniformity and optical properties of the preform deteriorate.

Another reported method for fabricating a GI preform involves using a very high rotation speed, as high as about 20,000 rpm. This method uses the principle that if a mixture of monomers or polymer-dissolving monomers having different density and refractive index is polymerized in a very strong centrifugal field, a concentration gradient is generated on account of a density gradient, causing a refractive index gradient to be generated. However, this method is limited in the selection of the monomers because the polymer having a relatively high density should have a refractive index lower than the monomer having a relatively low density.

The aforementioned methods suffer from problems caused by volume shrinkage during radical chain polymerization, which is common in the fabrication of GI preforms. Since volume shrinkage occurs when monomers are polymerized to produce a polymer, a preform for a plastic optical fiber fabricated under the rotation of a reactor will be hollow, or vacant, in its center, forming a tube-shaped cavity. Thus, it is necessary to fill the cavity with additional monomer in order to fabricate a cavity-free preform. The high-rotation speed method discussed above does not have any advantages over the conventional methods for fabricating a preform in this regard.

If one attempts to fill the cavity of the volume-shrunken preform, it exhibits a discrete refractive index distribution, causing sharp decreases in transmittance capacity and light quality. Accordingly, fiber so produced is limited in its practical uses. Furthermore, in the course of filling the cavity, the resultant preform may deteriorate in quality due to contact with minute quantities of dust, air or moisture. Additional machinery is required in order to prevent this contact, resulting in increased costs. Thus, the conventional methods described above have disadvantages, in that preforms for graded-index plastic optical fibers can be fabricated only under special conditions, and require exacting attention to molar volume, reaction ratio and refractive index differences.

### SUMMARY OF THE INVENTION

The present invention is therefore directed to an apparatus and method of forming a preform for a plastic optical fiber which substantially overcome one or more problems due to the limitations and disadvantages of the related art.

It is a feature of the present invention to provide a rotary reactor including an ultraviolet (UV) light-focusing optical system for inducing a polymerization reaction.

It is another feature of the present invention to provide a method for fabricating a preform for a plastic optical fiber using a rotary reactor including a UV light-focusing optical system.

At least one of the above and other features and advantages of the present invention may be realized by providing an apparatus for fabricating a preform for a plastic optical fiber including a rotary reactor including an introduction part having a reactant inlet though which a reactant is introduced into the rotary reactor, and including a transparent reaction part that is separated from the introduction part by a blocking wall having a flow path through which the reaction part is connected to the introduction part, the flow path disposed at the center of the blocking wall, a UV blocking wall for preventing UV irradiation of the introduction part, a UV light-focusing optical system including a UV lamp and arranged over the rotary reactor, and a system for moving the UV light-focusing optical system and the rotary reactor relative to each other in a radial direction of the rotary reactor. The apparatus may include a driving part for rotating the rotary reactor, and a fixing means for fixing the rotary reactor to the driving part. The apparatus may further include a pressurizing part for pressurizing the rotary reactor. The UV light-focusing optical system may include a parabolic reflector or a plano-convex lens arranged adjacent to the UV lamp for focusing UV light emitted from the UV lamp onto the reaction part. The apparatus may further include a temperature controlling part including an air inlet for feeding air heated by a heating line, an air outlet, and a temperature controller for controlling an inner temperature of the rotary reactor, and may include an angle-controlling part for adjusting a position of the rotary reactor within a range of from about 0° to about 90° with respect to the direction of gravity.

At least one of the above and other features and advantages may also be realized by providing a method of fabricating a preform for a plastic optical fiber using an apparatus for fabricating a preform for a plastic optical fiber, the method including filling a reaction part with a first component containing at least one monomer, a photopolymerization initiator and a chain transfer agent, introducing a second component having a different composition from the first component into a portion of an introduction part, and pressurizing and filling the other portions of the introduction part with an inert gas, and photopolymerizing the components while rotating the rotary reactor and moving the UV light-focusing optical system toward the center of the rotary reactor. The method may include forming a clad having a constant refractive index in the reaction part prior to filling the reaction part with the first component. The method may include introducing a second component into the introduction part that has a higher refractive index than the first component filled into the reaction part, such that a refractive index gradient increases towards the center. The method may include rotating the rotary reactor at a constant or non-constant speed. The method may include a non-constant rotation of a simple repetition of rotation at a high or low speed and stopping, or rotation according to a sinusoidal function or a function whose period, phase and/or amplitude is varied. The method may include varying a focusing area or a conveying speed of the UV light-focusing optical system. The method may include filling the first and second components into the reaction part and the introduction part, respectively, in the state of prepolymers, wherein the prepolymers are wholly or partly used. The method may include adding a material to the reaction and introduction parts, wherein the material has a good compatibility with a copolymer and a different refractive index from the first and second components and does not participate in a reaction between the first and second components. The method may include adding a monomer such as methylmethacrylate, benzylmethacrylate, phenylmethacrylate, 1-methylcyclohexylmethacrylate, cyclohexylmethacrylate, chlorobenzylmethacrylate, 1 phenylethylmethacrylate, 1,2-diphenylethylmethacrylate, diphenylmethylmethacrylate, furfurylmethacrylate, 1-phenylcyclohexylmethacrylate, pentachlorophenylmethacrylate, pentabromophenylmethacrylate, styrene, 2,2,2-trifluoroethylmethacrylate (TFEMA), 2,2,3,3,3-pentafluoropropylmethacrylate (PFPMA), 1,1,1,3,3,3-hexafluoroisopropylmethacrylate (HFIPMA), and/or 2,2,3,3,4,4,4-heptafluorobutylmethacrylate (HFBMA). The method may include adding a photopolymerization initiator such as 4-(p-tolylthio)benzophenone, 4,4′-bis(dimethylamino)benzophenone, or 2-methyl-4′-(methylthio)-2-morpholino-propiophenone; and a chain transfer agent such as n-butyl mercaptan, lauryl mercaptan, and/or dodecyl mercaptan. In an embodiment, the method may include adding a prepolymer, such as a prepolymer polymerized from methylmethacrylate, benzylmethacrylate, phenylmethacrylate, 1-methylcyclohexylmethacrylate, cyclohexylmethacrylate, chlorobenzylmethacrylate, 1-phenylethylmethacrylate, 1,2-diphenylethylmethacrylate, diphenylmethylmethacrylate, furfurylmethacrylate, 1-phenylcyclohexylmethacrylate, pentachlorophenylmethacrylate, pentabromophenylmethacrylate, styrene, 2,2,2-trifluoroethylmethacrylate (TFEMA), 2,2,3,3,3-pentafluoropropylmethacrylate (PFPMA), 1,1,1,3,3,3-hexafluoroisopropylmethacrylate (HFIPMA), and/or 2,2,3,3,4,4,4-heptafluorobutylmethacrylate (HFBMA). In an embodiment, the method may include adding a material having a different refractive index from the first and second components that does not participate in a reaction between the first and second components, such as triphenyl phosphate, diphenyl sulfide, diphenyl sulfoxide, benzyl benzoate, and/or diphenylene. At least one of the above and other features and advantages of the present invention may also be realized by providing a preform for a graded-index optical fiber fabricated by an embodiment of the methods disclosed and claimed herein.

According to still another aspect of the present invention, there is provided a preform for a plastic optical fiber fabricated by the method and/or apparatus described herein.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a perspective close-up view of a rotary reactor component of an apparatus for forming a preform for plastic optical fiber by successive UV polymerization;

FIG. 2 illustrates a perspective view of rotary reactor and UV light-focusing optical system components of an apparatus for forming a preform for plastic optical fiber by successive UV polymerization;

FIGS. 3a, 3b and 3c illustrate views of operating stages of an apparatus for forming a preform for plastic optical fiber by successive UV polymerization;

FIG. 4 is a graph that illustrates changes in the loss of light of a graded-index plastic optical fiber fabricated in Examples 1 and 2 of the present invention; and

FIG. 5 is a graph that illustrates transmission speed data of a preform for a graded-index plastic optical fiber fabricated in Example 2 of the present invention.

### DETAILED DESCRIPTION OF THE INVENTION

Korean Patent Application No. 2004-97646, filed on Nov. 25, 2004, in the Korean Intellectual Property Office, and entitled: “Apparatus and Method for Fabricating Preform for Plastic Optical Fiber by Successive UV Polymerization,” is incorporated by reference herein in its entirety.

The present invention will now be described in detail with respect to preferred embodiments as illustrated in the attached drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. As used herein, the words “reactant” and “reactants” are used interchangeably, and may refer to monomers, polymers, prepolymers, polymer-dissolving monomers, thermal initiators, photo initiators, chain transfer agents and/or other materials, and mixtures thereof. Like reference numerals refer to like elements throughout.

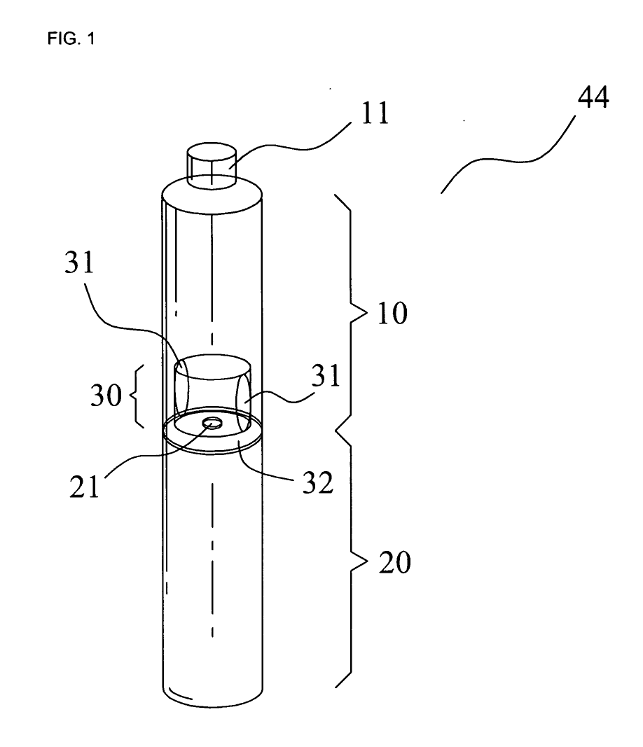

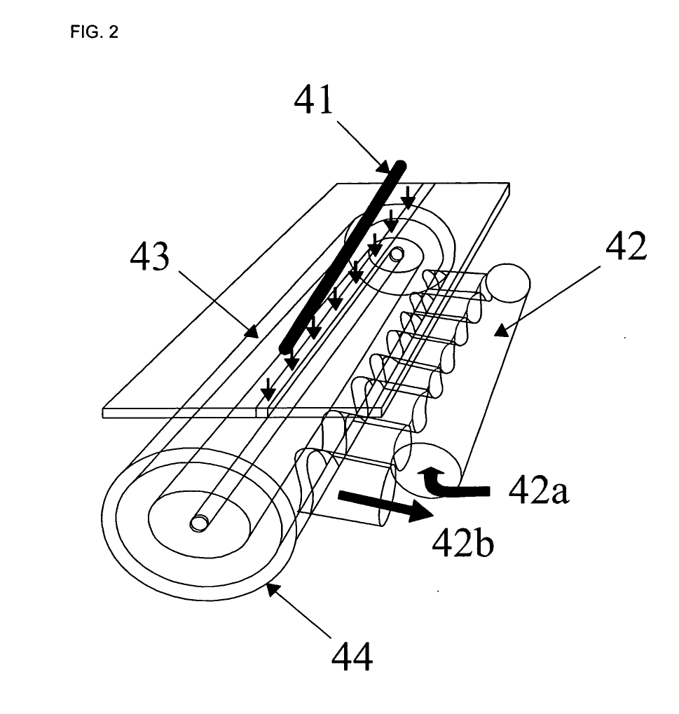

FIGS. 1 and 2 illustrate an apparatus for fabricating a preform for plastic optical fiber by successive UV polymerization, including a rotary reactor 44 and a UV light-focusing optical system 41. FIG. 1 illustrates a perspective view of a schematic of the rotary reactor 44. Preferably, the rotary reactor 44 is a cavity-preventing type rotary reactor, although embodiments of the present invention are not limited thereto. The rotary reactor 44 may preferably be cylindrical and may preferably be divided into an introduction part 10 and a reaction part 20. The introduction part 10 may include a reactant inlet 11 through which a reactant is fed into the rotary reactor 44. The reaction part 20 may include a housing defining an interior reaction region. The reaction part 20 may include a flow path 21 through which a reactant flows from the introduction part 10 to the reaction part 20.

A wall 32 and a cavity-preventing structure 30 may preferably be provided between the introduction part 10 and the reaction part 20. The wall 32 and the cavity preventing structure 30 may prevent any cavity that may have developed in the reactant inlet 11 from extending to the reaction part 20 when the rotary reactor 44 is under rotation. The cavity-preventing structure 30 may include one or more flow paths 31 through which reactant flows from the introduction part 10 to the reaction part 20 whereas the cavity cannot extend itself from the introduction part 10 to the reaction part 20.

FIG. 2 illustrates a perspective view of a schematic of the rotary reactor 44 with the UV light-focusing optical system 41. The UV light-focusing optical system 41 preferably includes one or more sources of UV light. The UV light-focusing system 41 may include a UV lamp. The UV light-focusing optical system 41 may be disposed on or over the rotary reactor 44. The UV light-focusing optical system 41 and the rotary reactor 44 may be movable relative to each other in a radial direction of the rotary reactor. The UV light-focusing optical system 41 may be coupled to a conveyor 43 to move the UV light-focusing optical system 41 relative to the rotary reactor 44, although the present invention is not limited to this embodiment. The UV light-focusing optical system 41 may be mounted to a pivot such that light emitted from the UV light-focusing optical system 41 can be swept across a portion of the rotary reactor 44. Alternatively, the UV light-focusing optical system 41 may be stationary relative to the rotary reactor 44, and may include a moveable mask interposed between the UV light-focusing optical system 41 and the rotary reactor 44, such that a limited area of the rotary reactor 44 is irradiated. The mask may include a rectangular cutaway or transparent region bordered by an opaque region. In another embodiment, the UV light-focusing optical system 41 may be stationary while the rotary reactor 44 is moved relative to the UV light-focusing optical system 41.

In an embodiment of the present invention, the UV light-focusing optical system 41 may be moved relative to the rotary reactor 44 such that successive portions of the rotary reactor 44 are irradiated. Accordingly, a narrow, lengthwise band or rectangular region of the reaction part 20 of the rotary reactor 44 is irradiated by the UV light-focusing optical system 41 and the introduction part 10 is not irradiated. Motion of the UV light-focusing optical system 41 relative to the rotary reactor 44 is preferably in a radial direction of the rotary reactor 44, whereby successive portions of the rotary reactor 44 are irradiated. Preferably, motion in a radial direction proceeds from a peripheral portion of the rotary reactor 44 to a central portion of the rotary reactor 44. In an embodiment, the reaction part 20 includes a reaction region defined by a housing that is approximately cylindrical, and the UV light-focusing optical system 41 provides a beam of light directed along a chord of the cylinder.

In an embodiment, the UV light-focusing optical system 41 may focus UV light. The UV light-focusing optical system 41 may be moveable or adjustable so as to focus or change the focus of the UV light, such as to widen and/or narrow the width of the lengthwise band of the reaction part 20 that is irradiated. For example, the UV light-focusing system 41 may include one or more adjustable mirrors and/or lenses that are adjustable to widen or narrow the successive portions of the reaction part 20 that are irradiated by the UV light-focusing system 41.

The rotary reactor 44 may include a temperature controller 42 for controlling a temperature of the rotary reactor 44. The temperature controller 42 may be used, for example, to regulate a rate of a reaction in the rotary reactor 44 and may be coupled to an air inlet 42a, an adiabatic system and an air outlet 42b. The air inlet 42a may provide hot air heated by a heating line, for example to increase a rate of reaction, or may provide cool air to cool the rotary reactor 44, for example to decrease a rate of reaction. The rotary reactor 44 may include a pressurizing part for applying pressure during a reaction. For example, the rotary reactor 44 may include a system for pressurizing the rotary reactor 44, the introduction part 10 and/or the reaction part 20 with an inert gas. The rotary reactor 44 may include an angle-controlling part for setting a position of the rotary reactor 44 to a desired angle, within a range of from about 0° (vertical) to about 90° (horizontal).

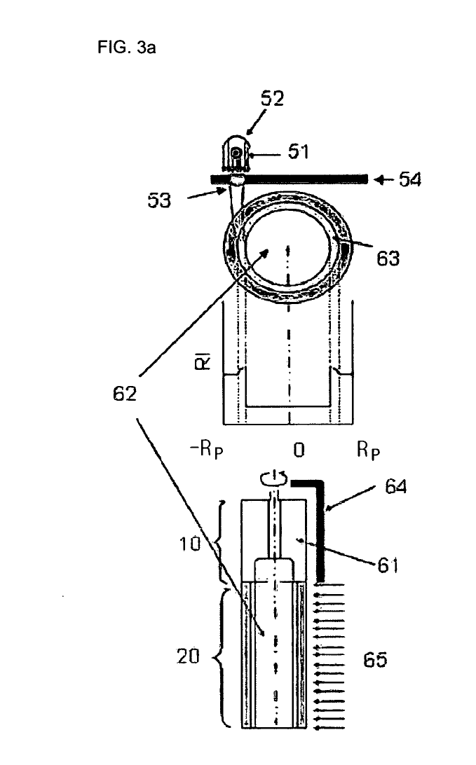

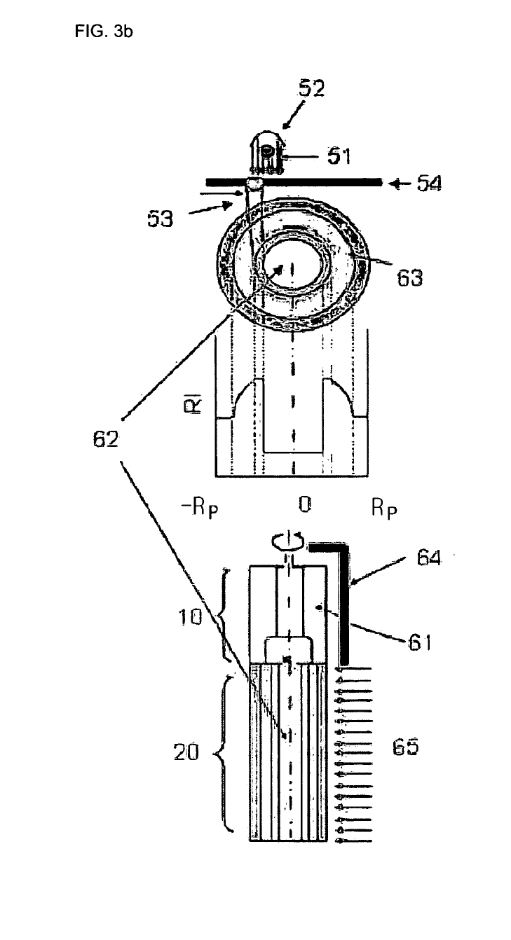

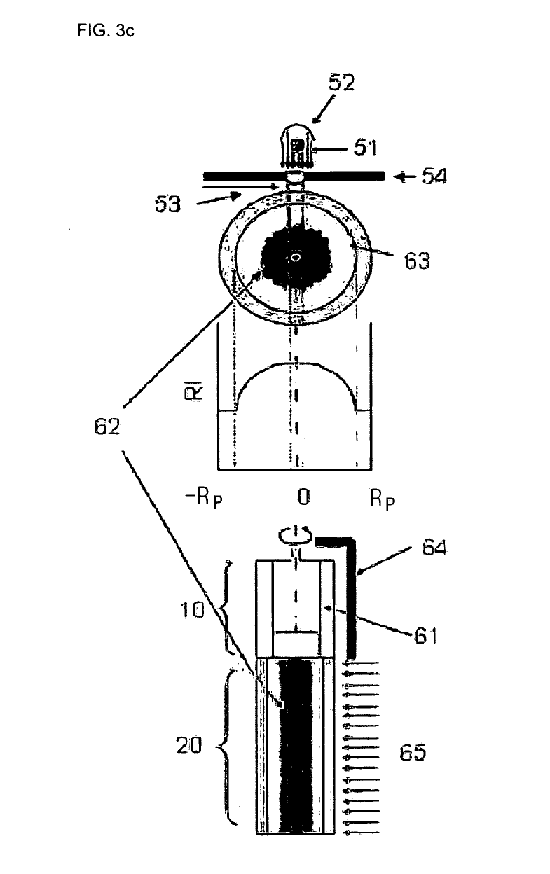

FIGS. 3a, 3b and 3c illustrate schematic views of operating states of an apparatus for fabricating a preform for plastic optical fiber by successive UV polymerization according to embodiments of the present invention, wherein a preform for a plastic optical fiber is fabricated using a rotary reactor 44. Preferably, the rotary reactor 44 is a cavity-preventing type rotary reactor. As illustrated in FIG. 3a, the UV light-focusing optical system 41 may include a UV lamp 51, and may further include a parabolic reflector 52 arranged over the UV lamp 51 and/or a piano-convex lens 53 arranged below the UV lamp 51 for focusing UV light 65 emitted from the UV lamp 51 onto the reaction part 20. The UV light-focusing optical system 41 may be arranged on a conveyer 54 movable in a radial direction of the rotary reactor 44, such that the reaction part 20 can be successively irradiated with UV light through radial movement of the conveyer 54.

The introduction part 10 and the reaction part 20 of the rotary reactor 44 may be separately charged with reactants. The refractive index of a material 61 in the introduction part 10 may be higher than that of a material 62 in the reaction part 20. If the composition of the material 61 in the introduction part 10 differs from the composition of the material 62 in the reaction part 20, when UV light 65 emitted from the UV light-focusing optical system 41 mounted to the conveyer 54 irradiates only a portion 63 of material 62, the portion 63 may polymerize and exhibit an increased refractive index due to the difference in the composition of the introduction part 10. The rotary reactor 44 may include a blocking wall 64 that blocks the UV light 65, such that blocking wall 64 helps prevent undesired UV irradiation of the material 61 in the introduction part 10. Thus, UV-light induced polymerization preferably takes place only in the reaction part 20.

As illustrated in FIGS. 3b and 3c, the UV light-focusing optical system 41 may be successively moved in a radial fashion toward the center of the rotary reactor 44 to successively induce polymerization of the reactants in reaction part 20, such that the refractive index of the resulting preform varies radially. Preferably, the UV light-focusing optical system 41 is moved while the reaction part 20 is rotating, such that the portions 63 polymerized by the UV light 65 emitted from the UV light-focusing optical system 41 are of limited width but cover the length of the reaction part 20, whereby the preform formed by the apparatus and methods of the present invention may exhibit a graded refractive index in the radial direction and a uniform refractive index in the lengthwise direction.

Optionally, the rotary reactor 44 may include provisions to reduce the vaporization of reactants from heat, e.g., heat generated during radial mixing. If vaporization of the reactants occurs, bubbles of the vaporized reactants during the rotation of the reaction part 20 may result in cavities in the preform. Pressurization of the rotary reactor 44, including pressurization of the introduction part 10 and/or pressurization of the reaction part 20, may help suppress the formation of bubbles caused by vaporization. Optionally, the rotary reactor 44 may include provisions to help bubbles escape from the reaction part 20 toward the introduction part 10, which may be advantageous in fabricating a cavity-free preform. Such provisions may include an angle-controlling part for setting a position of the rotary reactor 44 to a desired angle, preferably, within a range of from 0° (vertical) to 90° (horizontal).

Hereinafter, a method for fabricating a preform for a plastic optical fiber using the apparatus of the present invention will be described in detail.

A method according to an embodiment of the present invention may include filling the reaction part 20 of the rotary reactor 44 with a first component 62 containing at least one monomer, a photopolymerization initiator and a chain transfer agent; introducing a second component 61 having a different composition from the first component into a portion of the introduction part 10 of the rotary reactor 44, and optionally pressurizing and filling the other portions of the introduction part 10 with an inert gas; and photopolymerizing the reactants under the rotation of the rotary reactor 44 while moving the UV light-focusing optical system 41 in a radial fashion toward the center of the rotary reactor 44.

In an embodiment of the present invention, prior to filling the reaction part 20 with the first component 62, a clad having a constant refractive index may be formed in the reaction part 20.

In an embodiment of the present invention, a polymeric material having a refractive index gradient that increasing towards the center can be prepared by introducing a mixture into the introduction part 10, the mixture having a higher refractive index than the first component filled into the reaction part 20. In particular, this process can be usefully applied to the fabrication of a preform for a polymeric optical fiber having a graded-index refractive index distribution.

To obtain various refractive index gradients of polymeric materials, changes can be made to a rotation speed of the rotary reactor 44. Such changes may include, for example, one or more of the following: the simple repetition of rotation at a high or low speed and stopping; a sinusoidal function; or a function whose period, phase and/or amplitude is varied. In addition, polymeric materials having various refractive index gradients can be prepared by regulating the focusing area and/or the conveying speed of the UV light-focusing optical system 41.

In an embodiment, at least one component selected from the first and second components filled into the reaction part 20 and the introduction part 10, respectively, can be previously polymerized to prepare a prepolymer, and the prepolymer can be wholly or partly used. Various modifications to the method of the present invention are possible. For example, another material having a good compatibility with a copolymer to be prepared from the first and second components and a different refractive index from the first and second components may be added to obtain a desired polymeric material, although it does not participate in the reaction between the first and second components. Prepolymers may include those polymerized from methylmethacrylate, benzylmethacrylate, phenylmethacrylate, 1-methylcyclohexylmethacrylate, cyclohexylmethacrylate, chlorobenzylmethacrylate, 1-phenylethylmethacrylate, 1,2-diphenylethylmethacrylate, diphenylmethylmethacrylate, furfurylmethacrylate, 1-phenylcyclohexylmethacrylate, pentachlorophenylmethacrylate, pentabromophenylmethacrylate, styrene, 2,2,2-trifluoroethylmethacrylate (TFEMA), 2,2,3,3,3-pentafluoropropylmethacrylate (PFPMA), 1,1,1,3,3,3-hexafluoroisopropylmethacrylate (HFIPMA), and/or 2,2,3,3,4,4,4-heptafluorobutylmethacrylate (HFBMA). Examples of materials which have a different refractive index from the first and second components but do not participate in the reaction between the first and second components may include, but are not limited to, triphenyl phosphate, diphenyl sulfide, diphenyl sulfoxide, benzyl benzoate and/or diphenylene.

Two monomers having different refractive indices may be used as the first and second components to fabricate the preform for a plastic optical fiber, and may include, but are not limited to, methylmethacrylate, benzylmethacrylate, phenylmethacrylate, 1-methylcyclohexylmethacrylate, cyclohexylmethacrylate, chlorobenzylmethacrylate, 1-phenylethylmethacrylate, 1,2-diphenylethylmethacrylate, diphenylmethylmethacrylate, furfurylmethacrylate, 1-phenylcyclohexylmethacrylate, pentachlorophenylmethacrylate, pentabromophenylmethacrylate, styrene, 2,2,2-trifluoroethylmethacrylate (TFEMA), 2,2,3,3,3-pentafluoropropylmethacrylate (PFPMA), 1,1,1,3,3,3-hexafluoroisopropylmethacrylate (HFIPMA), and/or 2,2,3,3,4,4,4-heptafluorobutylmethacrylate (HFBMA).

If desired, when a clad is previously formed in the method of the present invention, a thermal polymerization initiator may be added to polymerize the monomers. Examples of the thermal polymerization initiator include, but are not limited to, 2,2′-azobis(isobutyronitrile), 1,1′-azobis(cyclohexanecarbonitrile), 2,2′-azobis(2,4-dimethylvaleronitrile), 2,2′-azobis(methylbutyronitrile), di-tert-butyl peroxide, lauroyl peroxide, benzoyl peroxide, tert-butyl peroxide, azo-tert-butane, azo-bis-isopropyl, azo-n-butane, di-tert-butyl peroxide, etc.

Examples of the photopolymerization initiator that may be used to polymerize the monomers in the method of the present invention include, but are not limited to, 4-(p-tolylthio)benzophenone, 4,4′-bis(dimethylamino)benzophenone and/or 2-methyl-4′-(methylthio)-2-morpholino-propiophenone. Examples of the chain transfer agent that may be added to the monomer mixture include, but are not limited to, n-butyl mercaptan, lauryl mercaptan and/or dodecyl mercaptan.

A preform for a plastic optical fiber fabricated by the method of the present invention may be subjected to thermal drawing to transform it to a graded-index plastic optical fiber (GI-POF) having a desired diameter, or may be processed to have a relatively thick strand form, which can be applied to a refractive index distribution lens and an image guide for picture transmission.

Embodiments of the present invention will now be described in more detail with reference to the following examples. However, these examples are given for the purpose of illustration and are not to be construed as limiting the scope of the invention.

### EXAMPLE 1

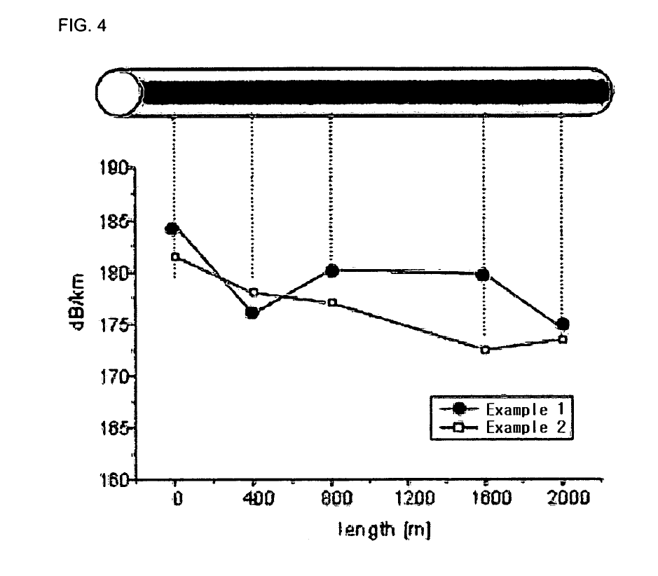

A reactant of 2,2′-azo-bis(isobutyronitrile) as a thermal polymerization initiator and n-butyl-mercaptan as a charge transfer agent in 100 mol % of methylmethacrylate (MMA) was charged into the reaction part 20 of a cavity-preventing type rotary reactor 44. The reactant was polymerized at a temperature of 75° C. for 24 hours while rotating the rotary reactor 44 at 2,000 rpm to form a polymethylmethacrylate (PMMA) clad. Thereafter, a reactant consisting of a methylmethacrylate/benzylmethacrylate (MMA/BzMA=95/5 mol/mol %) mixture, a UV photoinitiator (Irgacure 184), and n-butyl-mercaptan was charged into the reaction part 20, a mixture of methylmethacrylate/benzylmethacrylate (MMA/BzMA=80/20 mol/mol %) was charged into the introduction part 10, and then the introduction part 10 was pressurized to three (3) bar under nitrogen atmosphere. Polymerization was performed at a rotation speed of 2,000 rpm at 75° C. while the UV light-focusing optical system 41 was conveyed radially inward from the clad to the core at a speed of 0.5 mm/30 min. to fabricate a preform having a graded refractive index. After a thermal drawing process, the loss of light of the resultant plastic optical fiber was about 180 dB/km, as measured by the cut back method, illustrated in FIG. 4. The resultant plastic optical fiber exhibited uniform loss of light in its lengthwise direction, which is also illustrated in FIG. 4.

### EXAMPLE 2

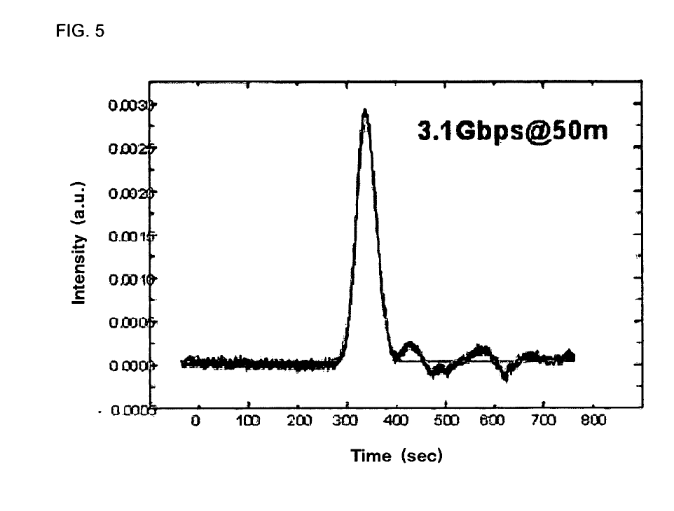

A reactant of 2,2′-azo-bis(isobutyronitrile) and n-butyl-mercaptan in MMA/TFPMA (80/20 mol/mol %) was charged into the reaction part 20. The reactant was polymerized at a temperature of 75° C. for 24 hours while rotating the rotary reactor 44 at 2,000 rpm to form a polymethylmethacrylate/trifluoropropylmethacrylate clad. Thereafter, a reactant consisting of a methylmethacrylate/trifluoropropylmethacrylate (MMA/TFPMA) (80/20 mol/mol %) mixture, a UV photoinitiator (Irgacure 184), and n-butyl-mercaptan was charged into the reaction part 20, a mixture of methylmethacrylate/trifluoropropylmethacrylate (MMA/TFPMA) (95/5 mol/mol %) was charged into the introduction part 10, and then the introduction part 10 was pressurized to three (3) bar under nitrogen atmosphere. Polymerization was performed at a rotation speed of 2,000 rpm at 75° C. while the UV light-focusing optical system 41 was conveyed radially inward from the clad to the core at a speed of 0.5 mm/30 min to fabricate a preform having a graded refractive index. After a thermal drawing process, the loss of light of the resultant plastic optical fiber was about 170 dB/km, as measured by the cut back method, illustrated in FIG. 4. The resultant plastic optical fiber exhibited uniform loss of light in its lengthwise direction, which is also illustrated in FIG. 4. The transmission speed of the GI-POF prepared using the preform was 3.1 Gbps@50 m, as determined through a pulse broadening experiment, as illustrated in FIG. 5.

As apparent from the above description, the apparatus and the method for fabricating a preform for a plastic optical fiber according to the present invention have the following advantages. When a chemical reaction or a physical phenomenon accompanying a volume shrinkage during rotation occurs, a series of troublesome operations, e.g., stopping of a reactor for filling a cavity formed at the center of the reactor and introduction of reactants can be avoided or minimized. Therefore, the present invention is advantageous in that a preform for a plastic optical fiber can be easily fabricated.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An apparatus for fabricating a preform for a plastic optical fiber, comprising:
a rotary reactor, the rotary reactor including:
an introduction part having a reactant inlet through which a reactant is introduced into the rotary reactor; and
a reaction part that is separated from the introduction part by a blocking wall having a flow path through which the reaction part is connected with the introduction part, the flow path disposed at the center of the blocking wall;
a UV blocking wall for preventing UV irradiation of the introduction part;
a UV light-focusing optical system including a UV lamp arranged over the rotary reactor; and
a system for moving the UV light-focusing optical system and the rotary reactor relative to each other in a radial direction of the rotary reactor.

2. The apparatus for fabricating a preform for a plastic optical fiber as claimed in claim 1, further comprising:
a driving part for rotating the rotary reactor; and
a fixing means for fixing the rotary reactor to the driving part.

3. The apparatus for fabricating a preform for a plastic optical fiber as claimed in claim 2, further comprising a pressurizing part for pressurizing the rotary reactor.

4. The apparatus for fabricating a preform for a plastic optical fiber as claimed in claim 1, wherein the UV light-focusing optical system further comprises a parabolic reflector or a plano-convex lens arranged adjacent to the UV lamp for focusing UV light emitted from the UV lamp onto the reaction part.

5. The apparatus for fabricating a preform for a plastic optical fiber as claimed in claim 1, wherein the apparatus further comprises a temperature controlling part including an air inlet for feeding air heated by a heating line, an air outlet, and a temperature controller for controlling an inner temperature of the rotary reactor.

6. The apparatus for fabricating a preform for a plastic optical fiber as claimed in claim 1, further comprising an angle-controlling part for adjusting a position of the rotary reactor within a range of from about 0° to about 90° with respect to the direction of gravity.

7. A method for fabricating a preform for a plastic optical fiber using an apparatus for fabricating a preform for a plastic optical fiber including a UV light-focusing optical system and a rotary reactor having a reaction part and an introduction part, the method comprising:
filling the reaction part with a first component containing at least one monomer, a photopolymerization initiator, and a chain transfer agent;
introducing a second component having a different composition from the first component into a portion of the introduction part, and pressurizing and filling the other portions of the introduction part with an inert gas; and
photopolymerizing the components while rotating the rotary reactor and moving the UV light-focusing optical system toward the center of the rotary reactor.

8. The method for fabricating a preform for a plastic optical fiber as claimed in claim 7, further comprising forming a clad having a constant refractive index in the reaction part prior to filling the reaction part with the first component.

9. The method for fabricating a preform for a plastic optical fiber as claimed in claim 7, wherein the second component introduced into the introduction part has a higher refractive index than the first component filled into the reaction part, such that a refractive index gradient increases towards the center.

10. The method for fabricating a preform for a plastic optical fiber as claimed in claim 7, wherein the rotary reactor is rotated at a constant or non-constant speed.

11. The method for fabricating a preform for a plastic optical fiber as claimed in claim 10, wherein the non-constant rotation is a simple repetition of rotation at a high or low speed and stopping, or depends on a sinusoidal function or a function whose period, phase, and/or amplitude is varied.

12. The method for fabricating a preform for a plastic optical fiber as claimed in claim 7, wherein the photopolymerization includes varying a focusing area or a conveying speed of a UV light-focusing optical system.

13. The method for fabricating a preform for a plastic optical fiber as claimed in claim 7, wherein the first and second components filled into the reaction part and the introduction part, respectively, are in the state of prepolymers, and wherein the prepolymers are wholly or partly used.

14. The method for fabricating a preform for a plastic optical fiber as claimed in claim 13, wherein the prepolymer includes at least one material selected from the group consisting of methylmethacrylate, benzylmethacrylate, phenylmethacrylate, 1-methylcyclohexylmethacrylate, cyclohexylmethacrylate, chlorobenzylmethacrylate, 1-phenylethylmethacrylate, 1,2-diphenylethylmethacrylate, diphenylmethylmethacrylate, furfurylmethacrylate, 1-phenylcyclohexylmethacrylate, pentachlorophenylmethacrylate, pentabromophenylmethacrylate, styrene, 2,2,2-trifluoroethylmethacrylate (TFEMA), 2,2,3,3,3-pentafluoropropylmethacrylate (PFPMA), 1,1,1,3,3,3-hexafluoroisopropylmethacrylate (HFIPMA), and 2,2,3,3,4,4,4-heptafluorobutylmethacrylate (HFBMA).

15. The method for fabricating a preform for a plastic optical fiber as claimed in claim 7, further comprising adding a material to the reaction and introduction parts, wherein the material has a good compatibility with a copolymer and a different refractive index from the first and second components and does not participate in a reaction between the first and second components.

16. The method for fabricating a preform for a plastic optical fiber as claimed in claim 15, wherein the material having a different refractive index from the first and second components that does not participate in a reaction between the first and second components is at least one material selected from the group consisting of triphenyl phosphate, diphenyl sulfide, diphenyl sulfoxide, benzyl benzoate, and diphenylene.

17. The method for fabricating a preform for a plastic optical fiber as claimed in claim 7, wherein the monomer includes at least one material selected from the group consisting of methylmethacrylate, benzylmethacrylate, phenylmethacrylate, 1-methylcyclohexylmethacrylate, cyclohexylmethacrylate, chlorobenzylmethacrylate, 1-phenylethylmethacrylate, 1,2-diphenylethylmethacrylate, diphenylmethylmethacrylate, furfurylmethacrylate, 1-phenylcyclohexylmethacrylate, pentachlorophenylmethacrylate, pentabromophenylmethacrylate, styrene, 2,2,2-trifluoroethylmethacrylate (TFEMA), 2,2,3,3,3-pentafluoropropylmethacrylate (PFPMA), 1,1,1,3,3,3-hexafluoroisopropylmethacrylate (HFIPMA), and 2,2,3,3,4,4,4-heptafluorobutylmethacrylate (HFBMA).

18. The method for fabricating a preform for a plastic optical fiber as claimed in claim 7, wherein the photopolymerization initiator includes at least one material selected from the group consisting of 4-(p-tolylthio)benzophenone, 4,4′-bis(dimethylamino)benzophenone, and 2-methyl-4′-(methylthio)-2-morpholino-propiophenone; and the chain transfer agent includes at least one material selected from the group consisting of n-butyl mercaptan, lauryl mercaptan, and dodecyl mercaptan.

19. A preform for a graded-index plastic optical fiber fabricated by the method according to claim 7.
